(19) United States
(12) Patent Application Publication
(10) Pub. No.: US 2012/0199961 A1
(43) Pub. Date: Aug. 9, 2012

(54) SEMICONDUCTOR PACKAGES HAVING LEAD FRAMES

(75) Inventor: Eun-Hee JUNG, Cheonan-si (KR)

(73) Assignee: Samsung Electronics Co., Ltd., Suwon-si (KR)

(21) Appl. No.: 13/367,610

(22) Filed: Feb. 7, 2012

(30) Foreign Application Priority Data
Feb. 8, 2011 (KR) 10-2011-0011148

(51) Int. Cl. H01L 23/495; H01L 23/48

(52) U.S. Cl. 257/676; 257/782; 257/E23.031; 257/E23.01

(57) ABSTRACT

Semiconductor packages include a semiconductor chip, a lead frame on which the semiconductor chip is mounted, and a mold layer to encapsulate the semiconductor chip and the lead frame. The lead frame is electrically connected to the semiconductor chip. The lead frame includes a first lead frame and a second lead frame. The first lead frame is electrically connected to the semiconductor chip by a plurality of bonding wires. The first lead frame has outer leads that protrude from the mold layer. The second lead frame is attached to the first lead frame by an insulating adhesion layer. The second lead frame provides a mounting surface on which the semiconductor chip is mounted. The first and second lead frames support the semiconductor chip.

### CROSS-REFERENCE TO RELATED APPLICATIONS

This application claims priority from and the benefit under 35 U.S.C. §119, of Korean Patent Application No. 10-2011-0011148, filed on Feb. 8, 2011, in the Korean Intellectual Property Office (KIPO), the entirety of which is incorporated herein by reference.

### BACKGROUND

1. Field

The present disclosure relates to semiconductor packages and, more particularly, to semiconductor packages having lead frames.

2. Discussion of the Background

In the semiconductor industry, techniques for packaging semiconductor devices have been increasingly demanded with the development of smaller electronic products and with the improvement of reliable mounts. For example, demands for the development of smaller electronic products have expedited techniques for scaling down the semiconductor packages to produce small and compact semiconductor packages close to semiconductor chip sizes mounted therein. Further, demands for more reliable mounts of the semiconductor packages have raised the importance of the packaging techniques which are capable of improving efficiency of mounting processes and mechanical and/or electrical reliability of the semiconductor packages after mounting.

### SUMMARY

Exemplary embodiments of the general inventive concept are directed to semiconductor packages. Additional features and utilities of the present general inventive concept will be set forth in part in the description which follows and, in part, will be obvious from the description, or may be learned by practice of the general inventive concept.

Exemplary embodiments of the general inventive concept provide a semiconductor package that includes a semiconductor chip, a lead frame on which the semiconductor chip is mounted, and a mold layer encapsulating the semiconductor chip and the lead frame. The lead frame is electrically connected to the semiconductor chip. The lead frame includes a first lead frame and a second lead frame. The first lead frame is electrically connected to the semiconductor chip by a plurality of bonding wires. The first lead frame has outer leads that protrude from the mold layer. The second lead frame is attached to the first lead frame by an insulating adhesion layer. The second lead frame provides a mounting surface on which the semiconductor chip is mounted. The first and second lead frames support the semiconductor chip.

In some exemplary embodiments, the second lead frame may be disposed on the first lead frame, and the insulating adhesion layer may be disposed between the first and second lead frames.

In some exemplary embodiments, the second lead frame may include a plate shaped die pad, and the first lead frame may include a plurality of line shaped leads disposed to be spaced apart from each other along a surface of the second lead frame opposite the mounting surface. Each end of the respective line shaped leads may extend edges of the die pad. Each of the leads may include a first sub-lead and a second sub-lead. The first sub-lead may extend in a first direction and having one of the outer leads, and the second sub-lead may extend from an end of the first sub-lead in a second direction, the second direction crossing the first direction. The second sub-lead may be connected to one of the bonding wires.

In some exemplary embodiments, the leads may extend in a first direction under the die pad so that both ends of the respective leads protrude from both the opposite edges of the die pad. One of the ends of the respective leads may correspond to a first end having a first length, and the other of the ends of the respective leads may correspond to a second end having a second length greater than the first length. The second end may include the outer lead, and at least one of the first and second ends may be connected to at least one of the bonding wires. The leads may be arrayed to be spaced apart from each other in a second direction perpendicular to the first direction under the die pad. The first and second ends of each of the leads may protrude from opposite edges of the die pad, respectively. The leads may be arrayed so that the first ends and the second ends of the leads are alternately arrayed in the second direction along an edge of the die pad.

In some exemplary embodiments, the leads may be arrayed to be spaced apart from each other in a second direction perpendicular to the first direction under the die pad. The first ends of the leads may protrude from a first edge of the die pad and are disposed to be spaced apart from each other in the second direction. The second ends of the leads may protrude from a second edge opposite the first edge of the die pad and are disposed to be spaced apart from each other in the second direction.

Exemplary embodiments of the general inventive concept provide a semiconductor package that includes at least one semiconductor chip electrically connected to a plurality of bonding wires, a plate shaped die pad having a top surface on which the at least one semiconductor chip is mounted and a bottom surface opposite the top surface, and a plurality of line shaped leads connected to the bonding wires and attached to the bottom surface of the die pad by an insulating adhesion layer between the leads and the die pad. Each of the leads includes a first end extending beyond an edge of the die pad, a second end extending beyond another edge of the die pad, and an overlap portion connecting the first end to the second end and overlapping with the die pad.

In some exemplary embodiments, the overlap portion may have a bent shape including a first sub-lead extending in a first direction and a second sub-lead extending in a second direction, the second direction crossing the first direction. The first sub-lead may include the first end and the second sub-lead includes the second end. The semiconductor chip may include a plurality of bonding pads arrayed in the first direction on at least one of both opposite edges of a top surface of the semiconductor chip. The bonding pads may be electrically connected to the first ends by the bonding wires.

In some exemplary embodiments, the overlap portion may extend in a first direction to have a straight line shape. The first ends and the second ends of the leads may extend beyond a first edge of the die pad and a second edge of the die pad opposite the first edge of the die pad. The first and second ends protruded from one of the first and second edges of the die pad may be alternately arrayed to be spaced apart from each other in a second direction crossing the first direction. The first and second ends protruded from one of the first and second edges of the die pad may be electrically connected to the semiconductor chip.

In some exemplary embodiments, the first ends may protrude from the first edge of the die pad to be spaced apart from each other in a second direction, the second direction crossing the first direction, and the second ends may extend beyond the second edge of the die pad to be spaced apart from each other in the second direction. The first ends or the second ends may be electrically connected to the semiconductor chip.

In some exemplary embodiments, the semiconductor chip may include a plurality of bonding pads arrayed in a second direction, the second direction crossing the first direction on an edge of a top surface thereof. The bonding pads may be electrically connected to the first ends, the second ends or the first and second ends by the bonding wires.

In some exemplary embodiments, the semiconductor package may further include a mold layer encapsulating the at least one semiconductor chip, the die pad, and the leads. The first ends or the second ends may protrude from the mold layer and may include outer leads connecting the at least one semiconductor chip to an external electronic device.

Exemplary embodiments of the general inventive concept provide a semiconductor lead frame that includes a first lead frame electrically connected to a semiconductor chip by a plurality of bonding wires, the first lead frame comprising outer leads that protrude from a mold layer, and a second lead frame attached to the first lead frame by an insulating adhesion layer, the second lead frame providing a mounting surface on which the semiconductor chip is mountable.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIGS. 1A and 1B are perspective views illustrating a lead frame used to fabricate a semiconductor package according to exemplary embodiments of the general inventive concept.

FIG. 1C is a perspective view illustrating a semiconductor package fabricated using a lead frame according to exemplary embodiments of the general inventive concept.

FIGS. 2A and 2B are perspective views illustrating a lead frame used to fabricate a semiconductor package according to exemplary embodiments of the general inventive concept.

FIG. 2C is a perspective view illustrating a semiconductor package fabricated using a lead frame according to exemplary embodiments of the general inventive concept.

FIGS. 3A and 3B are perspective views illustrating a lead frame used to fabricate a semiconductor package according to exemplary embodiments of the general inventive concept.

FIG. 3C is a perspective view illustrating a semiconductor package fabricated using a lead frame according to exemplary embodiments of the general inventive concept.

FIGS. 4A, 4B and 4C are perspective views illustrating semiconductor packages according to exemplary embodiments of the general inventive concept.

FIG. 5A is a block diagram illustrating a memory card including a semiconductor package according to exemplary embodiments of the general inventive concept.

FIG. 5B is a block diagram illustrating an information processing system including a semiconductor package according to exemplary embodiments of the general inventive concept.

### DETAILED DESCRIPTION OF THE EXEMPLARY EMBODIMENTS

Reference will now be made in detail to the exemplary embodiments of the present general inventive concept, examples of which are illustrated in the accompanying drawings, wherein like reference numerals refer to the like elements throughout. The exemplary embodiments are described below in order to explain the present general inventive concept while referring to the figures. It should be noted, however, that the general inventive concept is not limited to the following exemplary embodiments, and may be implemented in various forms. Accordingly, exemplary embodiments are provided only to disclose the general inventive concept. In the drawings, the illustrated exemplary embodiments of the general inventive concept are not limited to the specific examples provided herein and may be exaggerated for clarity.

The terminology used herein is for the purpose of describing particular exemplary embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the exemplary embodiments in the detailed description may be described with sectional views as ideal exemplary views of the inventive concept. Accordingly, shapes of the exemplary views may be modified according to manufacturing techniques and/or allowable errors. Therefore, the exemplary embodiments of the general inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limiting to the scope of the general inventive concept.

It will be also understood that although the terms first, second, third etc. may be used herein to describe various elements, these elements should not be limited by these terms. These terms are only used to distinguish one element from another element. Thus, a first element in some exemplary embodiments could be termed a second element in other exemplary embodiments without departing from the teachings of the present general inventive concept. Exemplary embodiments of the present general inventive concept explained and illustrated herein include their complementary counterparts.

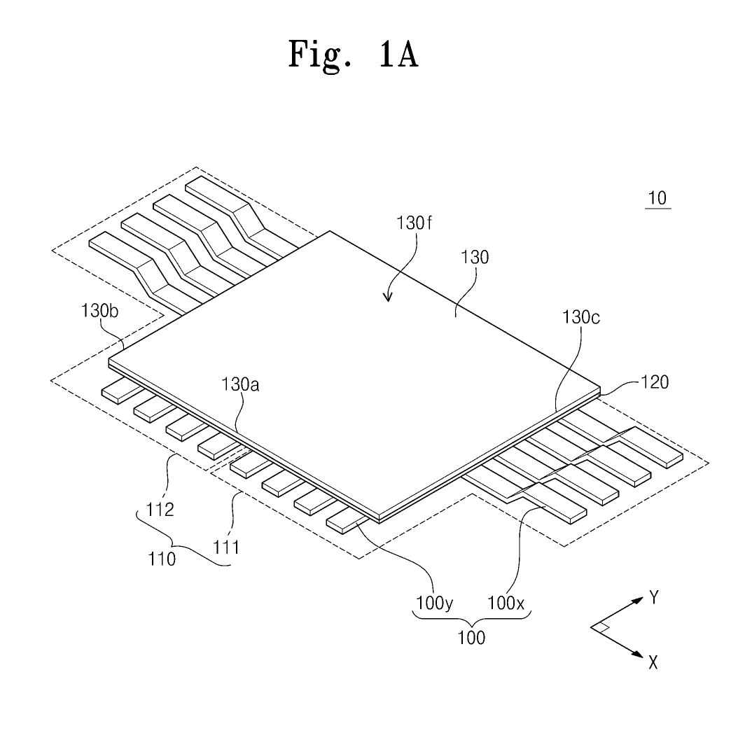

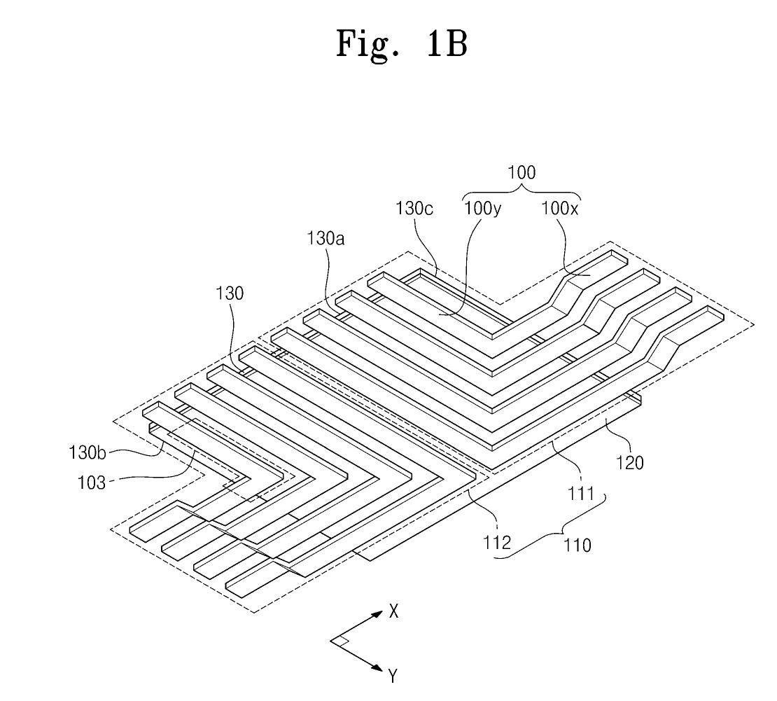

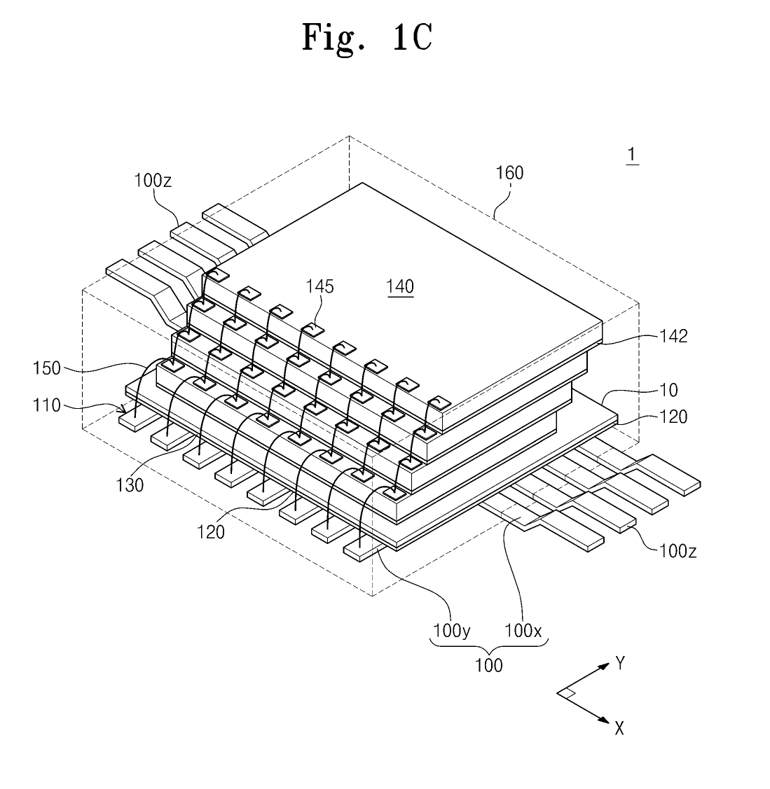

FIGS. 1A and 1B are perspective views illustrating a lead frame used to fabricate a semiconductor package according to exemplary embodiments of the general inventive concept, and FIG. 10 is a perspective view illustrating a semiconductor package fabricated using a lead frame according to exemplary embodiments of the general inventive concept.

Referring to FIGS. 1A and 1B, a lead frame 10 may include a lower lead frame 110 and an upper lead frame 130. The lower lead frame 110 may include leads each having a line shape, and the upper lead frame 130 may have a plate shape, each of which will be described further hereinafter. The upper lead frame 130 may provide a mounting surface 130f on which at least one semiconductor chip (e.g., 140 of FIG. 10) is mounted. The lower lead frame 110 may include a plurality of lead groups, for example, a first lead group 111 and a second lead group 112. Each of the first and second lead groups 111 and 112 may include a plurality of leads 100.

In the first lead group 111, each lead 100 may have a bent shape, for example, an L-shaped configuration in a plan view. That is, each lead 100 may include a first sub-lead 100x extending in an X-axis direction and a second sub-lead 100y extending from an end of the first sub-lead 100x in a Y-axis direction, the Y-axis direction crossing the X-axis direction. The Y-axis direction may intersect the X-axis direction at an angle of about 90 degrees; however, aspects need not be limited thereto such that the Y-axis and the X-axis may intersect at a different angle, for example, at or between 85 and 95 degrees. Each of the leads 100 may include a conductive material. For example, each lead 100 may include a metal layer having a relatively high conductivity. Each lead 100 may include a copper material, an iron-nickel (Fe—Ni) material, an aluminum material, a stainless steel material, or an alloy material having at least two thereof. Each of the leads 100 of each of the first and second lead groups 111 and 112 may have different lengths from each other. Further, the leads 100 of the first lead group 111 may be arrayed to be spaced apart from each other in order of length. For example, the longest L-shaped lead 100 may be disposed adjacent to a central portion of the upper lead frame 130, and the shortest L-shaped lead 100 may be disposed adjacent to an edge of the upper lead frame 130. The remaining leads 100 having medium lengths between the length of the longest L-shaped lead 100 and the length of the shortest L-shaped lead 100 may be disposed between the longest L-shaped lead 100 and the shortest L-shaped lead 100 in order of length, as illustrated in FIGS. 1A and 1B. In other words, the leads 100 of the first lead group 111 may be disposed in a nested-L arrangement in which each of the L-shaped leads 100 extends about same distances beyond edges of the upper lead frame 130. Further, the first sub-leads 100x of the leads 100 of the first lead group 111 may extend beyond an edge 130c of the upper lead frame 130 to about a same distance in the X-axis direction; and the second sub-leads 100y of the leads 100 of the first lead group 111 may extend beyond an edge 130a of the upper lead frame 130 to about a same distance in the Y-axis direction. The second lead group 112 may also have a same or similar configuration as the first lead group 111. That is, the first and second lead groups 111 and 112 may have a symmetrical structure around a line that passes through a central point of the upper lead frame 130 and is parallel with the Y-axis.

The lower lead frame 110 may be attached to a bottom surface of the upper lead frame 130 by an adhesion layer 120. The adhesion layer 120 may include an insulating adhesion layer, for example, an epoxy resin material or a silicone resin material. The upper lead frame 130 may have a rectangular shape. Portions of the lower lead frame 110 may protrude from the edges of the upper lead frame 130 toward outside the upper lead frame 130. For example, the first sub-leads 110x of the leads 100 of the first and second lead groups 111 and 112 of the lower lead frame 110 may protrude in opposite directions in the X-axis direction from both opposite edges 130c and 130b, respectively, of the upper lead frame 130 toward outside the upper lead frame 130, and the second sub-leads 110y of the leads 100 of the first and second lead groups 111 and 112 of the lower lead frame 110 may protrude from an edge 130a between both the opposite edges 130b and 130c of the upper lead frame 130 toward outside the upper lead frame 130. The length of the protrusions of the first sub-leads 100x may be equal to or greater than the length of the protrusions of the second sub-leads 100y. The protrusions of the first sub-leads 100x may have a straight shape. The protrusions of the first sub-leads 100x may have a bent shape in a side view, as illustrated in FIGS. 1A and 1B. For example, the first sub-leads 100x of at least one of the first and second lead groups 111 and 112 may be bent in a direction toward the upper lead frame 130 at an angle and may be bent in a direction away from the upper lead frame 130 at an angle, and may be bent in both the direction toward the upper lead frame 130 at the angle and in the direction away from the upper lead frame 130 at the same angle so that the first sub-leads 100x extend in two parallel planes. Further, each of the bends may be encapsulated by the mold layer 160; however, aspects need not be limited thereto.

The upper lead frame 130 may include a conductive material, such as a metal layer, like the lower frame lead 110. The upper lead frame 130 may include an insulating material, such as a glass layer or a resin layer, unlike the lower frame lead 110. In the event that the upper lead frame 130 includes an insulating material, the upper lead frame 130 may be different from the adhesion layer 120 between the lower lead frame 110 and the upper lead frame 130 in terms of material.

Referring to FIG. 10, a semiconductor package 1 may correspond to a thin small outline package (TSOP) including the lead frame 10 and one or more semiconductor chips 140 mounted on the lead frame 10. Each the semiconductor chips 140 may be memory devices or non-memory devices; however aspects need not be limited thereto such that the semiconductor chips 140 may include at least one memory device and at least one non-memory device. Each of the semiconductor chips 140 may have a one-row bonding pad structure including a plurality of bonding pads 145 arrayed in a single row on an edge of a top surface thereof. The bonding pads 145 may be arrayed in a direction (e.g., the X-axis direction) that the first sub-leads 100x extend.

The semiconductor chips 140 may have substantially an identical size. In a pair of directly stacked semiconductor chips 140, the upper semiconductor chip 140 may be shifted in the Y-axis direction to expose the bonding pads 145 of the lower semiconductor chip 140. An insulating adhesion layer 142 may be disposed between the semiconductor chips 140. Further, the insulating adhesion layer 142 may be disposed between the lowermost semiconductor chip 140 and the upper lead frame 130. The insulating adhesion layer 142 may include an epoxy resin material. A plurality of bonding wires 150 may be connected to the bonding pads 145 and the second sub-leads 100y, thereby electrically connecting the semiconductor chips 140 to the lead frame 10. The semiconductor package 1 may further include a mold layer 160 encapsulating the lead frame 10 and the semiconductor chips 140. The first sub-leads 100x may have protrusions 100z that protrude from at least one of opposite sidewalls of the mold layer 160 toward outside the mold layer 160. That is, the protrusions 100z of the first sub-leads 100x may extend in the X-axis direction. The protrusions 100z of the first sub-leads 100x may act as outer leads that electrically connect the semiconductor package 1 to an external electronic device, such as a printed circuit board, a main board, or a module substrate.

The lower lead frame 110 may electrically connect the semiconductor chips 140 to the external electronic device, i.e., the lower lead frame 110 may be similar to bonding pads electrically connected to the semiconductor chips 140. The upper lead frame 130 may be a die pad on which the semiconductor chips 140 are mounted. As illustrated in FIG. 1B, each lead 100 may have an overlap 103 that overlaps with the upper lead frame 130, and the overlaps 103 of the leads 100 may support the upper lead frame 130. Thus, the lower lead frame 110 may also act as a die pad together with the upper lead frame 130. As such, the lead frame 10 may have a double die pad structure. As a result, the plurality of semiconductor chips 140 may be stably mounted on the lead frame 10, and the semiconductor chips 140 and/or the semiconductor package 1 may have a decreased likelihood of warping.

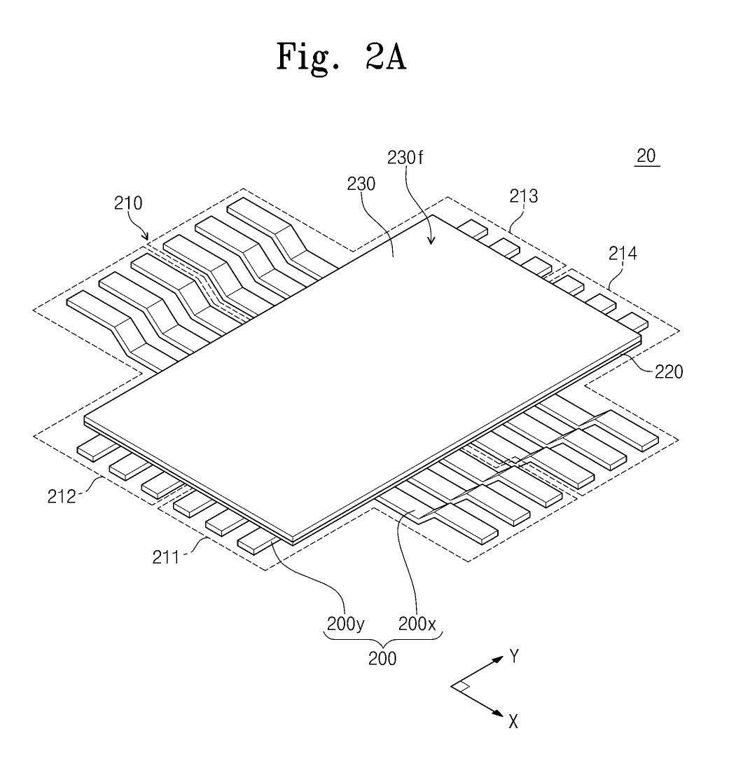

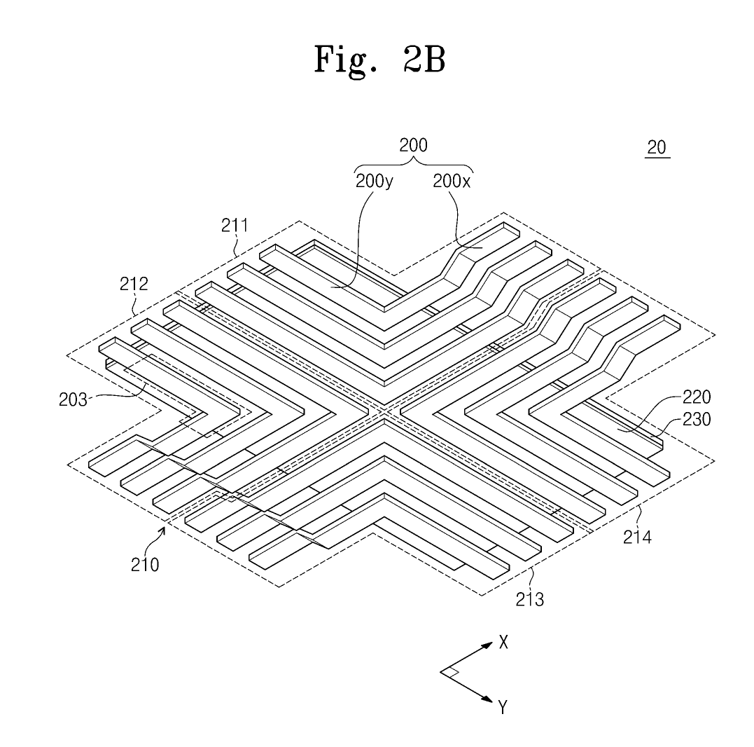

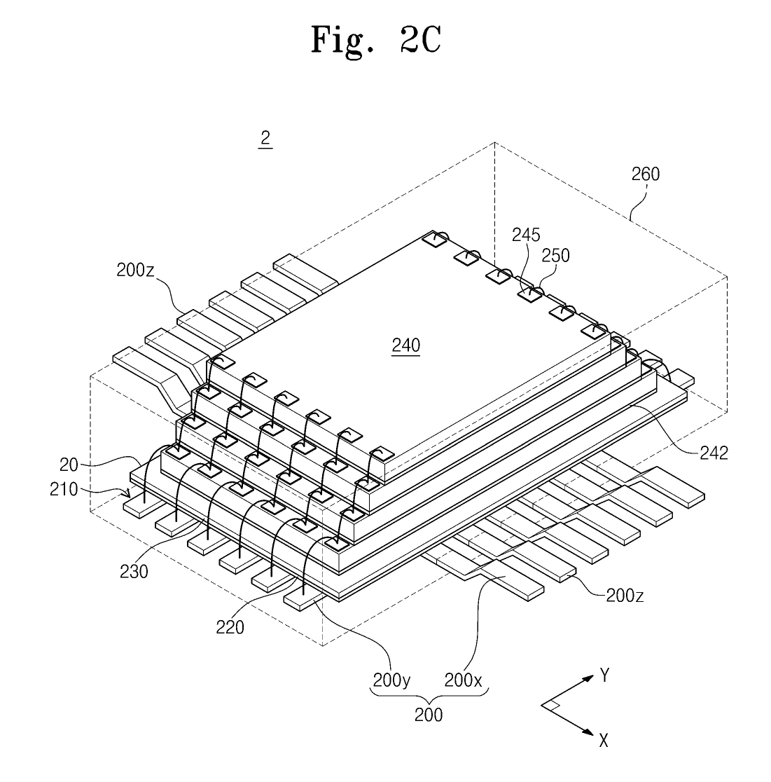

FIGS. 2A and 2B are perspective views illustrating a lead frame on which a semiconductor package is formed according to exemplary embodiments of the general inventive concept, and FIG. 2C is a perspective view illustrating a semiconductor package fabricated on the lead frame according to exemplary embodiments of the general inventive concept. To avoid duplicate explanations, descriptions of features or elements similar to those as set forth in the previous description may be omitted or briefly mentioned hereinafter. That is, differences between the following and the previous descriptions will be mainly described in detail hereinafter.

Referring to FIGS. 2A and 2B, a lead frame 20 may include an upper lead frame 230 and a lower lead frame 210 disposed under the upper lead frame 230. The upper lead frame 230 may provide a mounting surface 230f on which at least one semiconductor chip (e.g., 240 of FIG. 2C) is mounted and may have a rectangular shape. The lower lead frame 210 may be attached to a bottom surface of the upper lead frame 230 by an adhesion layer 220 and may include a plurality of L-shaped leads 200. The adhesion layer 220 may include an insulating adhesion layer, for example, an epoxy resin material or a silicone resin material. The lower lead frame 210 may include a plurality of lead groups. The lower lead frame 210 may include first, second, third, and fourth lead groups 211, 212, 213, and 214. The first to fourth lead groups 211, 212, 213, and 214 may be disposed in counterclockwise order under the upper lead frame 230, as illustrated in FIG. 2B.

The first to fourth lead groups 211, 212, 213 and 214 may be symmetric with each other, i.e., the first to fourth lead groups 211, 212, 213 and 214 may be symmetric may be symmetrical about two axes through the upper lead frame 230. For example, the first and second lead groups 211 and 212 may be disposed to be symmetric around a line passing through a central point of the upper lead frame 230 and extending in the Y-axis direction, and the third and fourth lead groups 213 and 214 may also be disposed to be symmetric around the same line passing through a central point of the upper lead frame 230 and extending in the Y-axis direction. Further, the first and fourth lead groups 211 and 214 may be disposed to be symmetric around a line passing through a central point of the upper lead frame 230 and extending in the X-axis direction, and the second and third lead groups 212 and 213 may also be disposed to be symmetric around the same line passing through a central point of the upper lead frame 230 and extending in the X-axis direction.

Each of the leads 200 may include a first sub-lead 200x extending in the X-axis direction and a second sub-lead 200y extending from an end of the first sub-lead 200x in the Y-axis direction crossing the X-axis direction. The first and second sub-leads 200x and 200y may protrude from edges of the upper lead frame 230 toward outside the upper lead frame 230. In the first lead group 211, the leads 200 may have different lengths from each other. Further, the leads 200 of the first lead group 211 may be arrayed to be spaced apart from each other in order of length. The second to fourth lead groups 212, 213 and 214 may also be arrayed to have a similar configuration to the first lead group 211.

Each of the leads 200 of each of the first to fourth lead groups 211, 212, 213, and 214 may have the first and second sub-leads 200x and 200y disposed in an L-shape similar to as described above. Each of the leads 200 of each of the first to fourth lead groups 211, 212, 213, and 214 may be disposed in a nested-L shape according to length. And, the first sub-leads 200x of the each of the leads 200 of each of the first to fourth lead groups 211, 212, 213, and 214 may extend beyond opposite edges of the upper lead frame 230 in the X-axis direction while the second sub-leads 200y of each of the leads 200 of each of the first to fourth lead groups 211, 212, 213, and 214 may extend beyond opposite edges of the upper lead frame 230 in the Y-axis direction. And, the first sub-leads 200x of at least one of the first to fourth lead groups 211, 212, 213, and 214 may be bent in a direction toward the upper lead frame 230 at an angle and may be bent in a direction away from the upper lead frame 230 at an angle, and may be bent in both the direction toward the upper lead frame 230 at the angle and in the direction away from the upper lead frame 230 at the same angle so that the first sub-leads 200x extend in two parallel planes.

Referring to FIG. 2C, a semiconductor package 2 may correspond to a thin small outline package (TSOP) including the lead frame 20 and one or more semiconductor chips 240 mounted on the lead frame 20. Each the semiconductor chips 240 may be memory devices or non-memory devices; however aspects need not be limited thereto such that the semiconductor chips 240 may include at least one memory device and at least one non-memory device. The semiconductor package 2 may further include a mold layer 260 encapsulating the lead frame 20 and the at least one semiconductor chip 240. Each of the semiconductor chips 240 may have a two-row bonding pad structure including a plurality of bonding pads 245 arrayed in two rows on opposite edges of top surfaces thereof. The semiconductor chips 240 may have different sizes from each other. In addition, the semiconductor chips 240 may be stacked on the upper lead frame 230 to have a pyramid shape or a stepped configuration, thereby exposing all the bonding pads 245 of the semiconductor chips 240.

An adhesion layer 242 may be disposed between the semiconductor chips 240. The adhesion layer 242 may include an insulating adhesion layer, for example, an epoxy resin material or a silicone resin material. Further, the adhesion layer 242 may be disposed between the lowermost semiconductor chip 240 and the upper lead frame 230. A plurality of bonding wires 250 may be connected to the bonding pads 245 and the second sub-leads 200y of each of the leads 200 of each of the first to fourth lead groups 211, 212, 213, and 214, thereby electrically connecting the semiconductor chips 240 to the lead frame 20. The first sub-leads 200x may have protrusions 200z that protrude from the opposite sidewalls of the mold layer 260 toward outside the mold layer 260. That is, the protrusions 200z of the first sub-leads 200x may extend in the X-axis direction. The protrusions 200z of the first sub-leads 200x may act as outer leads that electrically connect the semiconductor package 2 to an external electronic device, such as a printed circuit board, a main board, or a module substrate.

The upper lead frame 230 may be a die pad on which the semiconductor chips 240 are mounted. The lower lead frame 210 may electrically connect the semiconductor chips 240 to the external electronic device, i.e., the lower lead frame 110 may be similar to bonding pads electrically connected to the semiconductor chips 140. As illustrated in FIG. 2B, each lead 200 may have an overlap 203 that overlaps with the upper lead frame 230, and the overlaps 203 of the leads 200 may support the upper lead frame 230. Thus, the lower lead frame 210 and the upper lead frame 230 together may form a die pad and have a decreased likelihood of warping.

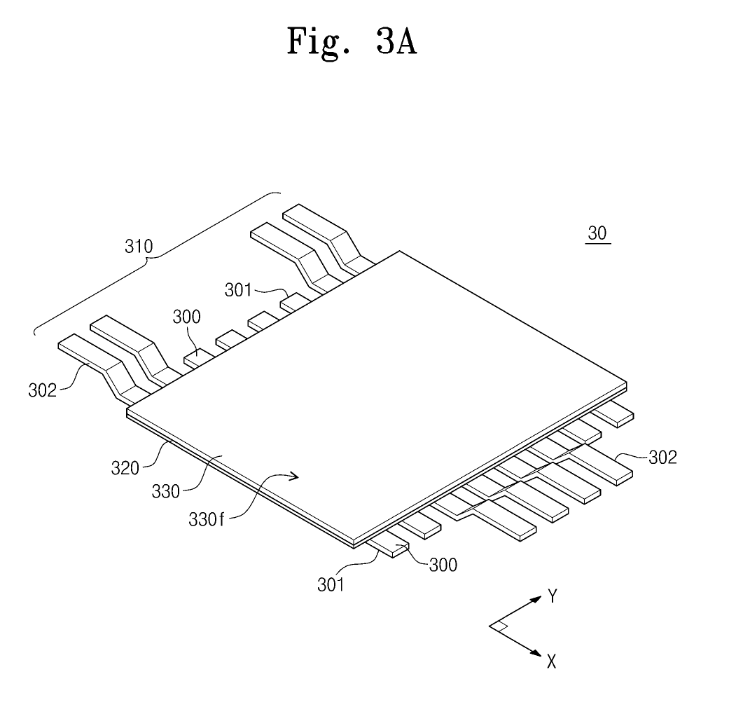

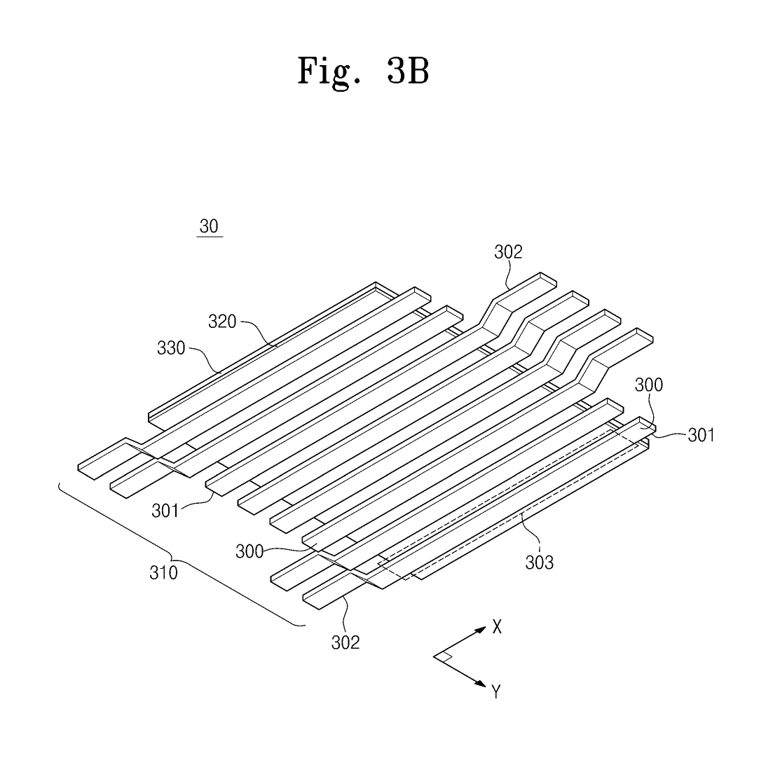

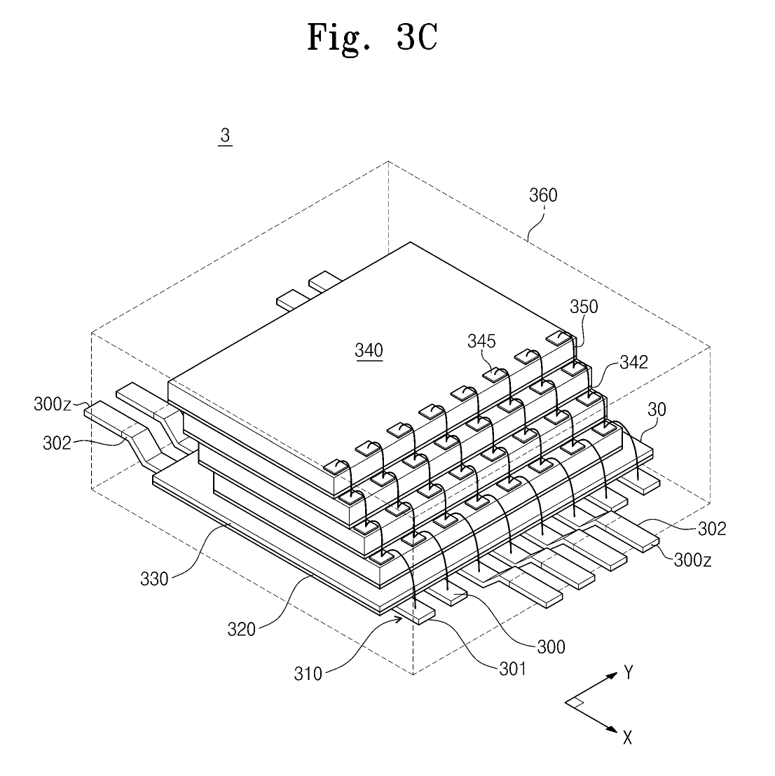

FIGS. 3A and 3B are perspective views illustrating a lead frame on which a semiconductor package is formed according to exemplary embodiments of the general inventive concept, and FIG. 3C is a perspective view illustrating a semiconductor package fabricated on the lead frame according to exemplary embodiments of the general inventive concept. To avoid duplicate explanations, descriptions of features or elements similar to those as set forth in the previous descriptions may be omitted or briefly mentioned hereinafter. That is, differences between the following and the previous descriptions will be mainly described in detail hereinafter.

Referring to FIGS. 3A and 3B, a lead frame 30 may include an upper lead frame 330 and a lower lead frame 310 disposed under the upper lead frame 330. The upper lead frame 330 may provide a mounting surface 330f on which at least one semiconductor chip (e.g., 340 of FIG. 3C) is mounted and may have a rectangular shape. The lower lead frame 310 may be attached to a bottom surface of the upper lead frame 330 by an adhesion layer 320. The adhesion layer 320 may include an insulating adhesion layer, for example, an epoxy resin material or a silicone resin material. The upper lead frame 330 be a die pad, and the lower lead frame 310 may be or provide bonging pads.

The lower lead frame 310 may include a plurality of line shaped leads 300 extending in the X-axis direction, i.e., the leads 300 of the lower lead frame 310 may extend in the X-axis direction in a substantially straight direction. First and second ends 301 and 302 of each lead 300 may protrude from both opposite edges of the upper lead frame 330, respectively. A length of the second ends 302 may be equal to or greater than that of the first ends 301. The second ends 302 may have a straight shape; however, aspects need not be limited thereto such that the second ends 302 may have a bent shape in a side view, as illustrated in FIGS. 3A and 3B. The second ends 302 of the lower lead frame 310 may be bent in a direction toward the upper lead frame 330 at an angle and may be bent in a direction away from the upper lead frame 330 at an angle, and may be bent in both the direction toward the upper lead frame 330 at the angle and in the direction away from the upper lead frame 330 at the same angle so that the second ends 302 extend in two parallel planes

The ends of the leads 300 may protrude from only one the opposite edges of the upper lead frame 330 and may not protrude from the other of the opposite edges of the upper lead frame 330. The second ends 302 at least one of the leads 300 may protrude from one of the opposite edges of the upper lead frame 330 and the second ends 302 of another of leads 300 may protrude from the other of the opposite edges of the upper lead frame 330, i.e., second ends 302 of the leads 300 need not be disposed on same sides of the upper lead frame 330 such that some of the leads 300 may be disposed in a first X-axis direction and other of the leads 300 may be disposed in a second X-axis direction, opposite the first X-axis direction.

Each of the leads 300 may have an overlap 303 that overlaps with the upper lead frame 330, and the overlaps 303 of the leads 300 may support the upper lead frame 330. Thus, the lower lead frame 310 and the upper lead frame 330 may together be a die pad.

The leads 300 may be arrayed to be spaced apart from each other in the Y-axis direction. Further, the leads 300 may include first to third groups of leads 300. The first and second groups of leads 300 may be respectively disposed adjacent to first and second opposite edges of the upper lead frame 330, and the third group of leads 300 may be disposed between the first and second groups of leads 300. Moreover, as illustrated in FIGS. 3A and 3B, the second ends 302 of the first and second groups of leads 300 may protrude from a third edge between the first and second opposite edges of the upper lead frame 330, and the second ends 302 of the third group of leads 300 may protrude from a fourth edge between the first and second opposite edges of the upper lead frame 330 and opposite the third edge of the upper lead frame 330.

Referring to FIG. 3C, a semiconductor package 3 may correspond to a thin small outline package (TSOP) including the lead frame 30 and one or more semiconductor chips 340 mounted on the lead frame 30. Each the semiconductor chips 340 may be memory devices or non-memory devices; however aspects need not be limited thereto such that the semiconductor chips 340 may include at least one memory device and at least one non-memory device. The semiconductor package 3 may further include a mold layer 360 encapsulating the lead frame 30 and the at least one semiconductor chip 340. An adhesion layer 342 may be disposed between the semiconductor chips 340. The adhesion layer 342 may include an insulating adhesion layer, for example, an epoxy resin material or a silicone resin material.

The lead frame 30 may have a double die pad structure. Each of the semiconductor chips 340 may have a one-row bonding pad structure including a plurality of bonding pads 345 arrayed in a single row on an edge of a top surface thereof. The bonding pads 345 may be arrayed in a direction (e.g., a Y-axis direction) perpendicular to a direction (e.g., an X-axis direction) in which the leads 300 extend. The semiconductor chips 340 may have substantially an identical size. In a pair of directly stacked semiconductor chips 340, the upper semiconductor chip 340 may be shifted in the X-axis direction to expose the bonding pads 345 of the lower semiconductor chip 340. A plurality of bonding wires 350 may be connected to the bonding pads 345 and the first and second ends 301 and 302 of the leads 300, thereby electrically connecting the semiconductor chips 340 to the lead frame 30. The first ends 301 not connected to the bonding wires 350 need not protrude from any edges of the upper lead frame 330. The first ends 301 and/or portions of the leads 300 adjacent to the second ends 302 may be connected to the bonding wires 350. End portions of the second ends 302 of the leads 300 may sufficiently protrude from an edge of the upper lead frame 330, thereby forming outer leads 300z. Further, each of the semiconductor chips 340 may have a two-row bonding pad structure including a plurality of bonding pads 345 arrayed in two rows on opposite edges of a top surface thereof, similar to as illustrated in FIG. 2C. In such case, the semiconductor chips 340 may have different sizes from each other. In addition, the semiconductor chips 340 may be stacked on the upper lead frame 330 to have a pyramid shape or a stepped configuration, thereby exposing all the bonding pads 345 of the semiconductor chips 340.

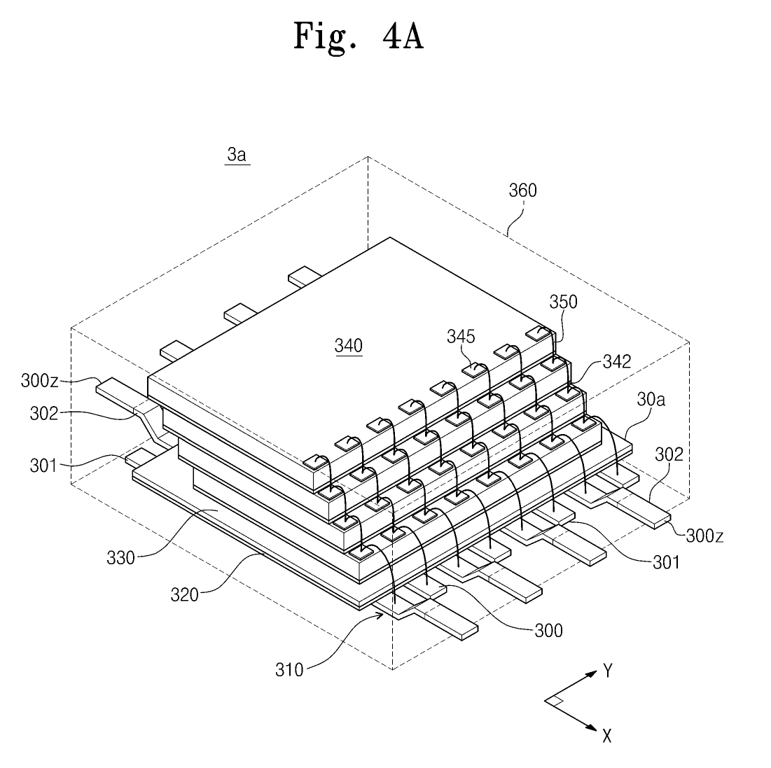

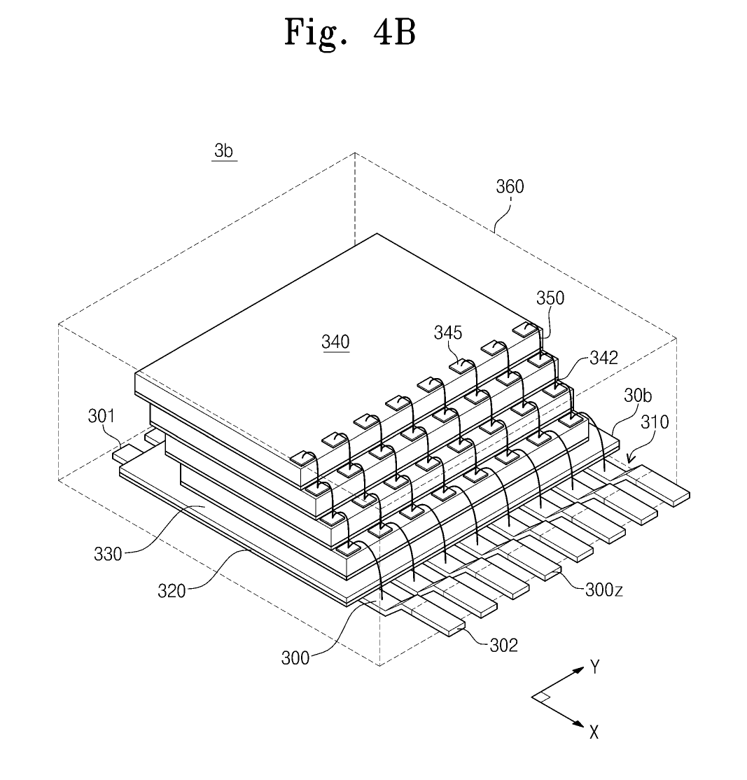

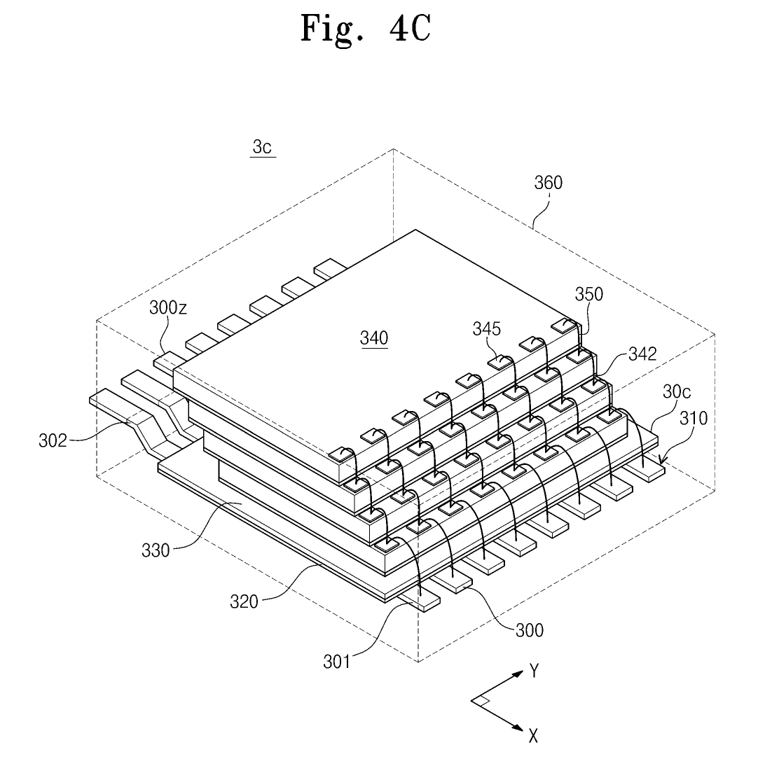

An array of the leads 300 is not limited to the above descriptions, i.e., the array of the leads 300 may be embodied in different forms from the above descriptions. FIGS. 4A, 4B, and 4C illustrate various arrangements of leads 300 according to exemplary embodiments of the general inventive concept.

FIGS. 4A, 4B and 4C are perspective views illustrating semiconductor packages according to exemplary embodiments of the general inventive concept. To avoid duplicate explanations, descriptions of features or elements similar to those as set forth in the previous descriptions may be omitted or briefly mentioned hereinafter. That is, differences between the following and the previous descriptions will be mainly described in detail hereinafter.

Referring to FIG. 4A, a semiconductor package 3a may include a lead frame 30a, one or more semiconductor chips 340 mounted on the lead frame 30a and wire-bonded to the lead frame 30a, and a mold layer 360 encapsulating the lead frame 30a and the semiconductor chips 340. The semiconductor chips 340 may have a one-row bonding pad structure. First and second ends 301 and 302 of each of leads 300 of the lead frame 30a may alternatingly protrude from both opposite edges of an upper lead frame 330, respectively. The leads 300 of the lead frame 30a may be arrayed in the Y-axis direction under the upper lead frame 330 so that the first ends 301 and the second ends 302 of the leads 300 are alternately arrayed in the Y-axis direction along an edge of the upper lead frame 330. End portions of the second ends 302 may further toward outside the mold layer 360, thereby forming outer leads 300z. The first ends 301 not connected to the bonding wires 350 need not protrude from any edges of the upper lead frame 330.

Referring to FIG. 4B, a semiconductor package 3b may be different from the semiconductor package 3a illustrated in FIG. 4A in terms of the array of the leads 300. For example, as shown in FIG. 4B, each the first ends 301 of the leads 300 may be disposed to be adjacent to a first sidewall of the upper lead frame 330, and all the second ends 302 of the leads 300 may be disposed to be adjacent to a second sidewall of the upper lead frame 330 opposite the first sidewall of the upper lead frame 330. The bonding wires 350 may be connected to the second ends 302. Thus, all the outer leads 300z may protrude from one edge of the mold layer 360. The elements other than the leads 300 and bonding wires may have a same or similar configuration as those of the semiconductor package 3a illustrated in FIG. 4A. The bonding wires 350 and the outer leads 300z may be disposed at a same side of the mold layer 360. The first ends 301 not connected to the bonding wires 350 need not protrude from any edges of the upper lead frame 330.

Referring to FIG. 4C, a semiconductor package 3c may be different from the semiconductor package 3b illustrated in FIG. 4B in terms of the array of the leads 300. That is, the leads 300 of the semiconductor package 3c may be disposed in the opposite direction to the leads 300 of the semiconductor package 3b illustrated in FIG. 4B. Thus, the bonding wires 350 may be connected to the first ends 301 of the leads 300. As a result, the bonding wires 350 may be disposed to be adjacent to a first side of the semiconductor package 3c, and the outer leads 300z may be disposed at a second side of the semiconductor package 3c opposite the first side of the semiconductor package 3c. The elements other than the leads 300 and the bonding wires 350 may have a same or similar configuration as those of the semiconductor package 3b illustrated in FIG. 4B.

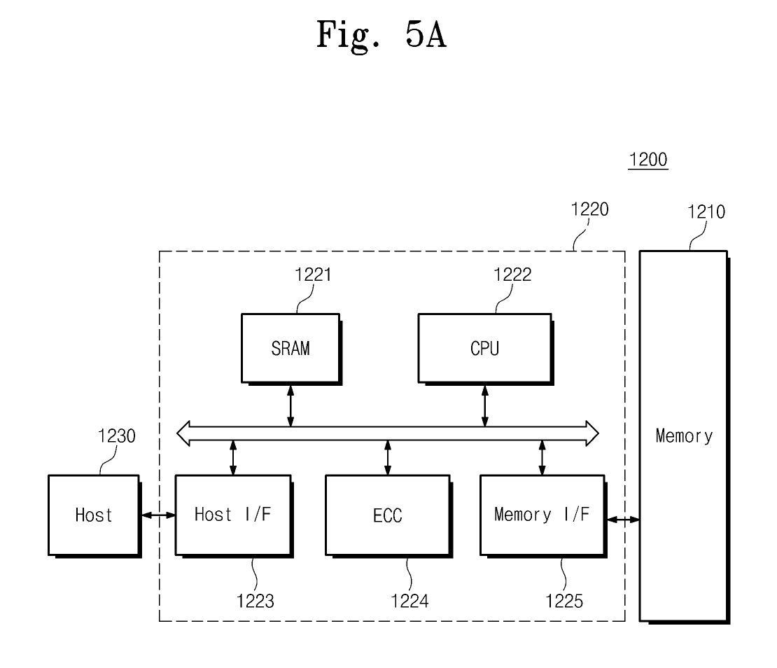

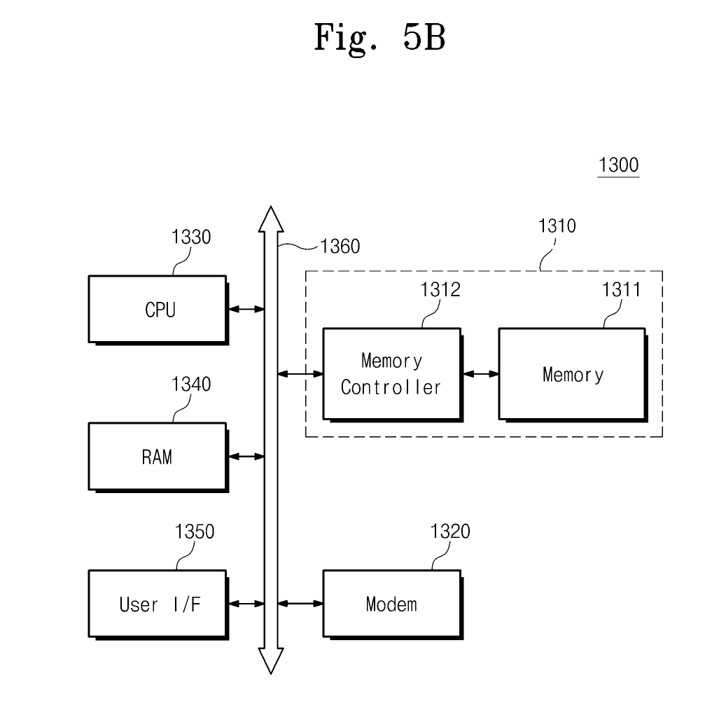

FIG. 5A is a block diagram illustrating a memory card including a semiconductor package according to exemplary embodiments of the general inventive concept, and FIG. 5B is a block diagram illustrating an information processing system including a semiconductor package according to exemplary embodiments of the general inventive concept.

Referring to FIG. 5A, a memory device 1210 including at least one of the semiconductor packages according to exemplary embodiments described above may be applied to a memory card 1200. The memory card 1200 may include a memory controller 1220 that controls data communication between a host 1230 and the memory device 1210. The memory controller 1220 may include a central processing unit (CPU) 1222, a static random access memory (SRAM) device 1221, a host interface unit 1223, an error check and correction (ECC) block 1224, and a memory interface unit 1225. The SRAM device 1221 may be used as an operation memory of the CPU 1222. The host interface unit 1223 may be configured to include a data communication protocol of the host 1230 connected to the memory card 1200. The ECC block 1224 may detect and correct errors of data which are read out from the memory device 1210. The memory interface unit 1225 may control the communication between the memory controller 1220 and the memory device 1210. The central processing unit (CPU) 1222 may control overall operations of the memory controller 1220.

Referring to FIG. 5B, an information processing system 1300 may include a memory system 1310 having at least one of the semiconductor packages according to exemplary embodiments of the general inventive concept. The information processing system 1300 may include a mobile system, a computer, or the like. The information processing system 1300 may include the memory system 1310, a modulator-demodulator (MODEM) 1320, a central processing unit (CPU) 1330, a random access memory (RAM) device 1340, and a user interface unit 1350 that communicate with each other through a data bus 1360. The memory system 1310 may include a memory device 1311 and a memory controller 1312. The memory system 1310 may have a substantially same or similar configuration as the memory card 1200 of FIG. 5A. The memory system 1310 may store data processed by the CPU 1330 or data transmitted from an external system. The information processing system 1300 may be applied to a memory card, a solid state disk, a camera image sensor, or an application chipset.

According to exemplary embodiments of the general inventive concept, one or more semiconductor chips may be mounted on a lead frame having a double die pad structure including a line shaped lower lead frame and a plate shaped upper lead frame. Thus, the semiconductor chips may be stably mounted on the lead frame, which may decreases instances of the semiconductor chips and/or the semiconductor package being warped. As a result, mechanical and electrical characteristics of the semiconductor package may be improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor package comprising:
a semiconductor chip;
a lead frame on which the semiconductor chip is mounted, the lead frame being electrically connected to the semiconductor chip; and
a mold layer encapsulating the semiconductor chip and the lead frame,
wherein the lead frame comprises:
a first lead frame electrically connected to the semiconductor chip by a plurality of bonding wires, the first lead frame comprising outer leads that protrude from the mold layer; and
a second lead frame attached to the first lead frame by an insulating adhesion layer, the second lead frame providing a mounting surface on which the semiconductor chip is mounted.

2. The semiconductor package of claim 1, wherein the second lead frame is disposed on the first lead frame and the insulating adhesion layer is disposed between the first and second lead frames.

3. The semiconductor package of claim 1, wherein the second lead frame comprises a plate shaped die pad,
wherein the first lead frame comprises a plurality of line shaped leads disposed to be spaced apart from each other along a surface of the second lead frame opposite the mounting surface, and
wherein each end of the respective line shaped leads extends beyond edges of the die pad.

4. The semiconductor package of claim 3, wherein each of the leads comprises:
a first sub-lead extending in a first direction and comprising one of the outer leads; and
a second sub-lead extending from an end of the first sub-lead in a second direction, the second direction crossing the first direction,
wherein the second sub-lead is connected to one of the bonding wires.

5. The semiconductor package of claim 3, wherein the leads extend in a first direction so that the ends of the respective leads extend beyond opposite edges of the die pad,
wherein one of the ends of the respective leads is a first end having a first length and the other of the ends of the respective leads is a second end having a second length greater than the first length, and
wherein the second end includes the outer lead and at least one of the first and second ends is connected to at least one of the bonding wires.

6. The semiconductor package of claim 5, wherein the leads are arrayed to be spaced apart from each other in a second direction perpendicular to the first direction,
wherein the leads are arrayed so that the first ends and the second ends of the leads are alternately arrayed in the second direction along an edge of the die pad.

7. The semiconductor package of claim 5, wherein the leads are arrayed to be spaced apart from each other in a second direction perpendicular to the first direction,
wherein the first ends of the leads protrude from a first edge of the die pad and are disposed to be spaced apart from each other in the second direction, and
wherein the second ends of the leads protrude from a second edge opposite the first edge of the die pad and are disposed to be spaced apart from each other in the second direction.

8. The semiconductor package of claim 1, wherein the first lead frame comprises a plurality of leads having first ends and second ends, the outer leads being formed at the first ends of the leads, the first ends being bent at angle toward the second lead frame.

9. The semiconductor package of claim 8, wherein the first ends are additionally bent away from the second lead frame such that the leads extend in two parallel planes.

10. The semiconductor package of claim 9, wherein each of the bends of the first ends is encapsulated by the mold layer.

11. A semiconductor package comprising:
at least one semiconductor chip electrically connected to a plurality of bonding wires;
a plate shaped die pad having a top surface on which the at least one semiconductor chip is mounted and a bottom surface opposite the top surface;
a plurality of line shaped leads connected to the bonding wires and attached to the bottom surface of the die pad by an insulating adhesion layer between the leads and the die pad,
wherein each of the leads comprises:
a first end extending beyond an edge of the die pad;
a second end extending beyond another edge of the die pad; and
an overlap portion connecting the first end to the second end and overlapping with the die pad;
a mold layer encapsulating the at least one semiconductor chip, the die pad, and the leads,
wherein the first ends or the second ends protrude from the mold layer and include outer leads connecting the at least one semiconductor chip to an external electronic device.

12. The semiconductor package of claim 11, wherein the overlap portion has a bent shape including a first sub-lead extending in a first direction and a second sub-lead extending in a second direction, the second direction crossing the first direction, and
wherein the first sub-lead includes the first end and the second sub-lead includes the second end.

13. The semiconductor package of claim 12, wherein the semiconductor chip includes a plurality of bonding pads arrayed in the first direction on at least one of opposite edges of a top surface of the semiconductor chip, and
wherein the bonding pads are electrically connected to the first ends by the bonding wires.

14. The semiconductor package of claim 11, wherein the overlap portion extends in a first direction to have a straight line shape, and
wherein the first ends and the second ends of the leads extend beyond a first edge of the die pad and a second edge of the die pad opposite the first edge of the die pad.

15. The semiconductor package of claim 14, wherein the first and second ends are alternately arrayed to be spaced apart from each other in a second direction, the second direction crossing the first direction, and
wherein at least some of the first and second ends are electrically connected to the semiconductor chip.

16. The semiconductor package of claim 14, wherein the first ends extend beyond the first edge of the die pad to be spaced apart from each other in a second direction, the second direction crossing the first direction, and the second ends protrude from the second edge of the die pad to be spaced apart from each other in the second direction, and
wherein the first ends or the second ends are electrically connected to the semiconductor chip.

17. The semiconductor package of claim 14, wherein the semiconductor chip includes a plurality of bonding pads arrayed in a second direction, the second direction crossing the first direction, along an edge of a top surface thereof, and
wherein the bonding pads are electrically connected to the first ends, the second ends or at least some of the first and second ends by the bonding wires.

18. A semiconductor lead frame comprising:
a first lead frame electrically connected to a semiconductor chip by a plurality of bonding wires, the first lead frame comprising outer leads that protrude from a mold layer; and
a second lead frame attached to the first lead frame by an insulating adhesion layer, the second lead frame providing a mounting surface on which the semiconductor chip is mountable,
wherein the first lead frame comprises a plurality of nested L-shaped leads, ends of which extend beyond adjacent edges of the second lead frame.

19. The semiconductor lead frame of claim 18, wherein the first lead frame comprises a first lead group and a second lead group, each of the first and second lead groups comprising a plurality of nested L-shaped leads, each of the L-shaped leads having a first end and a second end, the second ends of each of the L-shaped leads comprising the outer leads,
wherein the second ends of the L-shaped leads of the first and second lead groups extend beyond opposite edges of the second lead frame, and
wherein the first ends of the L-shaped leads of the first and second lead groups extend beyond an edge of the second lead frame disposed between the opposite edges of the second lead frame.

20. The semiconductor lead frame of claim 18, wherein the first lead frame comprises a first lead group, a second lead group, a third lead group and a fourth lead group, each of the first to fourth lead groups comprising the plurality of nested L-shaped leads, each of the L-shaped leads having a first end and a second end, the second ends of each of the L-shaped leads comprising the outer leads,
the second ends of the L-shaped leads of the first and fourth lead groups extend beyond a first edge of the second lead frame, and the second ends of the L-shaped leads of the second and third lead groups extend beyond a second edge of the second lead frame, the first and second edges of the second lead frame being opposite from each other, and
wherein the first ends of the L-shaped leads of the first and second lead groups extend beyond a third edge of the second lead frame, and the second ends of the L-shaped leads of the third and fourth lead groups extend beyond a fourth edge of the second lead frame, the third and fourth edges of the second lead frame being opposite from each other and disposed between the first and second edges of the second lead frame.
